(19) United States
(12) Patent Application Publication
(10) Pub. No.: US 2026/0227464 A1
(43) Pub. Date: Aug. 6, 2026

(54) MAGNETIC FIELD SENSOR SYSTEM WITH A TEMPERATURE RESPONSE-COMPENSATED OUTPUT SIGNAL AND METHOD FOR THE TEMPERATURE RESPONSE-COMPENSATION OF AN OUTPUT SIGNAL OF A MAGNETIC FIELD SENSOR SYSTEM

(71) Applicant: SENIS AG, Zug (CH)

(72) Inventors: Radivoje POPOVIC, Zug (CH); Sasa SPASIC, Zug (CH); Thomas KALTENBACHER, Zug (CH)

(21) Appl. No.: 19/128,541

(22) PCT Filed: Nov. 9, 2023
(86) PCT No.: PCT/IB2023/061331

§ 371 Date: May 8, 2025

(30) Foreign Application Priority Data
Nov. 9, 2022 (DE) 10 2022 129 671.7

(51) Int. Cl. G01R 33/00; G01R 33/06

(52) U.S. Cl. CPC G01R 33/0082; G01R 33/06

(57) ABSTRACT

A magnetic field sensor system with a temperature response-compensated output signal comprises a magnetic field sensor subsystem for temperature response compensation of an output signal, which preferably comprises two interconnected subsystems, and a method for temperature response.

### TECHNICAL AREA

The present invention relates to a magnetic field sensor system with a temperature response compensated output signal according to claim 1 and to a method for temperature response compensation of an output signal of a magnetic field sensor system according to claim 11 or claim 12.

### STATE OF THE ART

Sensors for measuring a magnetic field, in particular Hall magnetic field sensors, are known from the state of the art in a sufficiently wide variety and large number.

The basics of Hall magnetic field sensors are described in great detail, for example, in R. S. Popovic: “Hall-effect devices”, Journal for Sensors and Actuators, Volume 17, Issues 1-2, 3 May 1989, Pages 39-53 or in R. S. Popovic “Hall Effect Devices”, 2nd Edition CRC Press Taylor & Francis Group, LLC 2003, ISBN: 978-1-4200-3422-6.

Furthermore, the present invention relates to the disclosure of U.S. Pat. No. 6,366,076 B1. Therein a current sensor is described, which combines the signals from a low-frequency magnetic field sensor, such as a Hall effect sensor, and an inductive coil, such as a Rogowski coil, in a summing device and feeds these summed signals into a low-pass filter.

From DE 102018128469 B4 a magnetic sensor system with a magnetic sensor, such as a Hall magnetic sensor, an induction loop or a coil is known, which is connected in series with the Hall magnetic sensor and the output signal is fed to a low-pass filter.

These two inventions of U.S. Pat. No. 6,366,076 B1 and DE 102018128469 disclose a measuring principle of how to obtain a broadband (current) sensor by combining a low-frequency magnetic field sensor, such as a Hall effect sensor, and an inductive coil, whereby the signals of the respective signal paths are explicitly (U.S. Pat. No. 6,366,076 B1) and implicitly (DE 102018128469) summed.

In the case of these inventions described in U.S. Pat. No. 6,366,076 B1 and DE 102018128469, the measuring principle and the sensor structure itself, as well as the arrangement of the sensor within a measuring circuit, are associated with undesirable side effects. For example, the input measurement signal is relatively strongly limited in its bandwidth, for example an output measurement signal superimposed by noise.

A well-known method for reducing offset and low frequency noise of Hall effect component is the use of a switch-based three-phase current technique known as spinning current technique (so-called spinning current) in combination with the so-called chopper stabilisation technique. The use of this combination in sensor systems that include a Hall-effect sensor leads to a reduction in the offset and low-frequency noise of the Hall-effect component and an amplifier that amplifies the Hall voltage.

Although these and other approaches described in the above-mentioned prior art provide new methods and circuit arrangements, they do not remotely provide a solution for stabilising and tracking the optimum parameters for a smooth frequency response of the output signal of such a sensor system.

In addition, magnetic field sensor systems with one or more magnetic field sensors are also known from DE 10 2008 061 067 A1 or DE 10 2021 102 051 A1. The aspect that the temperature response of the one or more magnetic field sensors can be compensated as a function of a current source clock signal derived from an oscillator by means of its supply current is neither known from the prior art in the given context, nor suggested to the skilled person from it.

### OBJECT OF THE INVENTION

The object of the invention is to stabilise the operation of a magnetic field sensor system comprising a magnetic field sensor and an inductive element, which can be connected in series or combined with an explicit summing element, under a wide range of environmental influences.

### Solution of the Problem

To solve the problem, a magnetic field sensor system with the features according to claim 1 and a method according to claim 11 or claim 12 are provided. Further advantageous designs and embodiments of a magnetic field sensor system and the method according to claim 12 result from the combination of further features according to subclaims 2 to 10.

### DESCRIPTION OF THE INVENTION

A magnetic field sensor system with a temperature response-compensated output signal Vₒᵤₜ comprises a magnetic field sensor subsystem for temperature response compensation of the output signal Vₒᵤₜ, which preferably comprises two interconnected subsystems.

A first subsystem of the magnetic field sensor subsystem comprises one or more magnetic field sensors selected from the group consisting of Hall effect sensors or other galvano-magnetic sensors such as a magnetic tunnel resistor (TMR), a giant magneto resistor (GMR), a sensor based on the colossal magneto-resistive effect (CMR) or a sensor based on the anisotropic magneto-resistive effect (AMR).

A second subsystem of the magnetic field sensor subsystem comprises a power source for supplying power to the one or more magnetic field sensors.

The magnetic field sensor system also comprises a low-pass filter and one or more inductive elements connected to this or these magnetic field sensors of the first subsystem either directly or via a summer.

For temperature response compensation of the magnetic field sensor system, the current source supplies the one or more magnetic field sensors with a supply current Iₕ in such a way that the temperature response of the one or more magnetic field sensors can be compensated by means of the supply current Iₕ as a function of a current source clock signal derived from an oscillator.

Preferably, the low-pass filter is designed to change its cut-off frequency foo as a function of a filter clock signal so that the temperature dependence of at least one magnetic field sensor can also be compensated.

Preferably, the frequency of the filter clock signal and/or the current source clock signal can be varied in the event of a deviation from a nominal frequency in such a way that the magnetic sensitivity of the one or more magnetic field sensors and the cut-off frequency f_{co} of the low-pass filter are proportional to the frequency of a common clock signal.

Preferably, the current source for the magnetic field sensor and/or the low-pass filter each comprise one or more switched capacitor circuits.

Preferably, the capacitance of one or more capacitors of the one or more switched capacitor circuits are programmable.

Preferably, the oscillator is a voltage-controlled oscillator.

In embodiments of a magnetic field sensor system, the common clock signal is formed by synchronising the filter clock signal and the current source clock signal.

In embodiments of a magnetic field sensor system, the magnetic field sensor system further comprises a compensation control unit configured to provide the filter clock signal, the current source clock signal, or any combination thereof.

In embodiments of a magnetic field sensor system, the magnetic field sensor subsystem comprises a further subsystem as a third subsystem with an amplifier for amplifying an output voltage Vₕ output by at least one magnetic field sensor as a magnetic field sensor signal modulated by switchable contacts.

In embodiments of a magnetic field sensor system, the magnetic field sensor system and/or the magnetic field sensor subsystem for a spinning current operation of a magnetic field sensor and/or a chopper stabilisation of the amplifier has switchable contacts in addition to the switchable contacts, which both relate to the same clock signal.

The invention thus represents an essential optimisation of a magnetic field sensor system comprising one or more magnetic field sensors, one or more inductive elements, such as an induction coil and/or one or more induction loops, as well as a low-pass filter, since those signals which are generated by a magnetic field in at least one magnetic field sensor and in at least one inductive element are combined with one another and passed through the low-pass filter together.

This has the advantage that at relatively low frequencies of the magnetic field, a virtually frequency-independent signal from the magnetic field sensor system is present. The signal of at least one inductive element is proportional to the frequency of the magnetic field. If these two signals are now combined and passed through a low-pass filter, the result is an output signal from the sensor that is frequency-independent from direct current or direct voltage up to very high frequencies.

The low-pass filter to be used here is a first-order low-pass filter with a cut-off frequency equal to the frequency at which the amplitude characteristics of the magnetic field sensor subsystem for the magnetic field sensor and the inductive element are equal in such a way that they intersect at a common point, as shown in FIG. 1. This means that the cut-off frequency f_{co} of the low-pass filter must fulfil the following condition:

$${f}_{co} = ( {S}_{h} * {G}_{h} ) / ( 2 * π * A * {G}_{c} ) \qquad ( 1 )$$

Sₕ describes the absolute magnetic sensitivity of the magnetic field sensor of the magnetic field sensor subsystem, Gₕ and G_{c} are the amplification factors of the signal coming from the magnetic field sensor and from the inductive element. In the case of an induction coil as an inductive element, A is the area of the induction coil or the effective area of the induction coil, which can be calculated by

$$A = {N}_{c} \times {A}_{a} \qquad ( 2 )$$

N_{c} is the number of turns of the induction coil and Aa is the average area of one turn of the induction coil.

The advantage of such a magnetic field sensor system, based on the combination of a magnetic field sensor, preferably an induction coil as an inductive element and a low-pass filter, is thus also the resulting large bandwidth and low noise.

Embodiments of such a magnetic field sensor system can also include an integrator instead of a low-pass filter, since an integrator has the same technical effect as a low-pass filter if their time constants are the same in each case.

Equation (1) shows the relationship between the parameters of the magnetic field sensor subsystem, preferably the induction coil as the inductive element, and the low-pass filter, which are optimally selected.

The present invention shows how to stabilise the parameters of the components of the magnetic field sensor system so that they retain their optimum values regardless of external influences.

Equation (1) is always fulfilled as soon as the magnetic sensitivity of the magnetic field sensor and the cut-off frequency of the low-pass filter are proportional to a common clock signal as the reference clock signal.

For example, the absolute magnetic sensitivity of the magnetic field sensor is given by

$${S}_{h} = {C}_{h} * {f}_{cl} \qquad ( 3 )$$

where Kₕ describes a proportionality coefficient and f_{cl} the frequency of the reference clock, and the cut-off frequency of the low-pass filter, i.e. the frequency at which the filter has attenuated the signal amplitude by −3 dB, is given by

$${f}_{co} = {C}_{f} \& {f}_{cl} \qquad ( 4 )$$

with K_{f} as a further proportionality coefficient.

The ratios in equations (3) and (4) can be fulfilled by implementing the current source, which supplies the magnetic field sensor with current, and/or the low-pass filter as switched capacitors.

Suitable circuits are shown in the book “Switched Capacitor Circuits”, Phillip E Allen, Springer Netherlands, 1984. A suitable switched capacitor current source is disclosed in the US patent U.S. Pat. No. 4,374,357A.

The absolute magnetic sensitivity of the magnetic field sensor is proportional to the supply current Iₕ

$${S}_{h} = {S}_{hi} * {I}_{h} \qquad ( 5 )$$

whereas Sₕᵢ is the current-related sensitivity of the magnetic field sensor.

If this current source for the supply current of the magnetic field sensor is now implemented as a switched capacitor circuit, the average current of this source can be expressed as follows:

$${I}_{h} = {V}_{r} * {C}_{i} * {f}_{cl} \qquad ( 6 )$$

Vᵣ is the reference voltage, Cᵢ is the capacitance of the capacitor in this circuit, and f_{cl} stands for the frequency of the associated clock signal, the current source clock signal.

If we now replace the supply current Iₕ in equation (5) with the expression from equation (6), the result is

$${S}_{h} = {S}_{hi} * {V}_{r} * {C}_{i} * {f}_{cl} . \qquad ( 7 )$$

Now introduce the following notation:

$${K}_{h} = {S}_{hi} * {V}_{r} * {C}_{h} , \qquad ( 8 )$$

Equation (7) can thus be rewritten in the same form as equation (3).

The coefficient Kₕ is practically temperature-independent if the reference voltage Vᵣ is designed to have an opposite temperature dependence compared to the current-related sensitivity of the magnetic field sensor Sₕᵢ.

This means that the source of the reference voltage Vᵣ is designed such, that it has a positive temperature coefficient if the current-related sensitivity has a negative temperature coefficient, and thus the combination of the two signals is temperature-independent. This can be expressed with the following inequality:

$${S}_{hi} * {V}_{r} \neq f ( T ) \qquad ( 9 )$$

The condition in equation (9) is common for magnetic field sensors based on the Hall effect. Typically, Sₕᵢ has a linear temperature dependence of approx. −0.1%/° C. Thus, to fulfil equation (9), Vᵣ must have a linear temperature coefficient of approx. +0.1%/° C.

The cut-off frequency of a first-order low-pass filter, which is implemented as a switched capacitor circuit, can be calculated using the following equation

$${f}_{co} = ( {C}_{1} / {C}_{2} ) * {f}_{cl} / ( 2 * π ) \qquad ( 10 )$$

This expression is well known from various textbooks. If the following notation is introduced:

$${K}_{f} = ( {C}_{1} / {C}_{2} ) / ( 2 * π ) \qquad ( 11 )$$

then equation (10) can be rewritten such that it takes the same form as equation (4).

If f_{(co)} is replaced by equation (10) in equation (1) and Sₕᵢ by equation (7), the following relationships are obtained:

$${C}_{1} / {C}_{2} = ( {S}_{hi} * {V}_{r} * {C}_{i} * {G}_{h} ) / ( A * {G}_{c} ) \qquad ( 12 )$$

Thus, the condition for the optimum operation of the magnetic field sensor system, carried out according to the disclosed invention, is shown by the validity of equation (12), which now replaces equation (1).

The validity of equation (12) can be considered practically independent of environmental factors if:
C₁, C₂, and Cᵢ are designed as integrated capacitors. If these capacitors are designed as poly-silicon or MOS capacitors (abbreviation for Metal Oxide Semiconductor), they are practically temperature-independent; and/or
A is the area of the induction coil or induction loop or effective area of the coil, which is also practically independent of temperature; and/or
Gₕ/G_{c} is the ratio of the voltage gain factors of integrated amplifiers, which can be made largely independent of environmental influences by careful design and balancing, as well as placement on the same chip substrate; and/or
the product Sₕᵢ*Vᵣ can be made independent of temperature by the validity of equation (10).

This means that the magnetic field sensor system under consideration is set once, i.e. the parameters are adjusted so that equations (1) and (13) are fulfilled and the settings are retained for any operating temperatures.

Embodiments of a magnetic field sensor system have the advantage that the initial setting can be advantageously designed by implementing at least one of the capacitances C₁, C₂ to Cᵢ according to equation (12) as a digitally programmable capacitance.

An advantageous implementation of a so-called ratiometric sensor system, which has a magnetic sensitivity proportional to a reference voltage, such as the voltage of the power supply of the magnetic field sensor system. This means that the clock generator, which serves as a common clock source (reference clock), can be designed as a voltage-controlled oscillator.

Embodiments can also be used in a magnetic field sensor system in which the magnetic field sensor is a Hall effect sensor with a Hall element as the sensor element or another galvano-magnetic sensor with a magneto-resistive resistor element as the sensor element.

A method for temperature response compensation of an output signal of a magnetic field sensor system comprising a magnetic field sensor subsystem comprising interconnected subsystems, wherein a first subsystem comprises one or more magnetic field sensors selected from the group consisting of Hall effect sensors or other galvano-magnetic sensors and a second subsystem of the magnetic field sensor subsystem comprising a power source for supplying power to the one or more magnetic field sensors, wherein the magnetic field sensor system further comprises a low pass filter, and one or more inductive elements electrically connected to this oder or these magnetic field sensors of the subsystem directly or via a summer, comprising the following steps:
determining a supply current as a function of a current source clock signal derived from an oscillator, thereby compensating for the temperature behaviour of the one or more magnetic field sensors; and
supplying the one or more magnetic field sensors with the determined supply current using the current source.

A method for temperature response compensation of an output signal of a magnetic field sensor system having the features of one of the previously described embodiments of a magnetic field sensor system according to any one of claims 1 to 10, comprises the steps of:
determining a supply current as a function of a current source clock signal derived from an oscillator, thereby compensating for the temperature behaviour of the one or more magnetic field sensors; and
supplying the one or more magnetic field sensors with the determined supply current using the current source.

Accordingly, it is also advantageous to use one of the methods described above for temperature response compensation of an output signal of a magnetic field sensor system according to the embodiments described above.

Further advantages result from the figures. These show in

FIG. 1 a frequency-voltage diagram of the frequency responses of partial voltages of a magnetic field sensor system connected to an induction coil as an inductive element as a function of the frequency of a magnetic field;

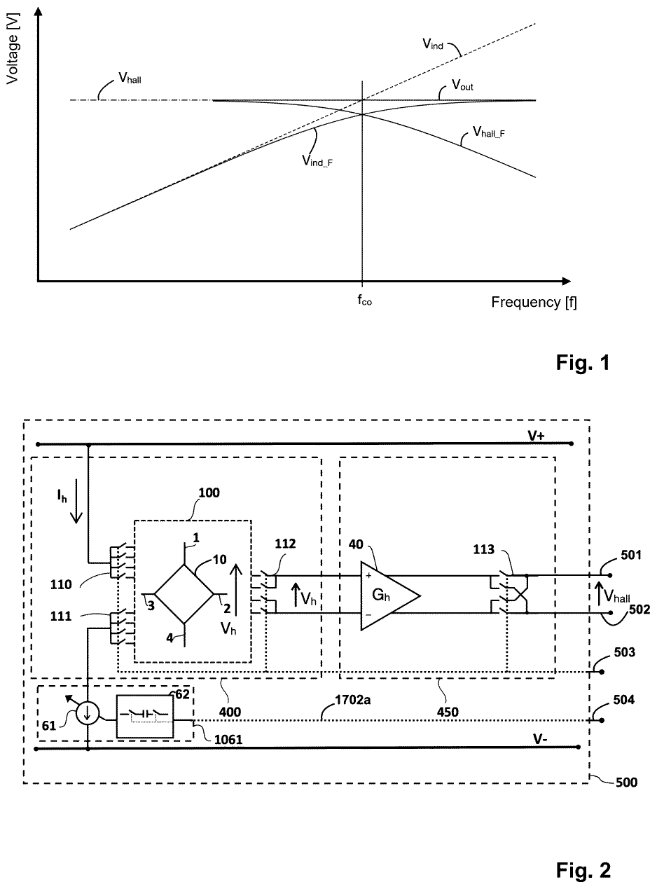

FIG. 2 a block diagram of a magnetic field sensor subsystem;

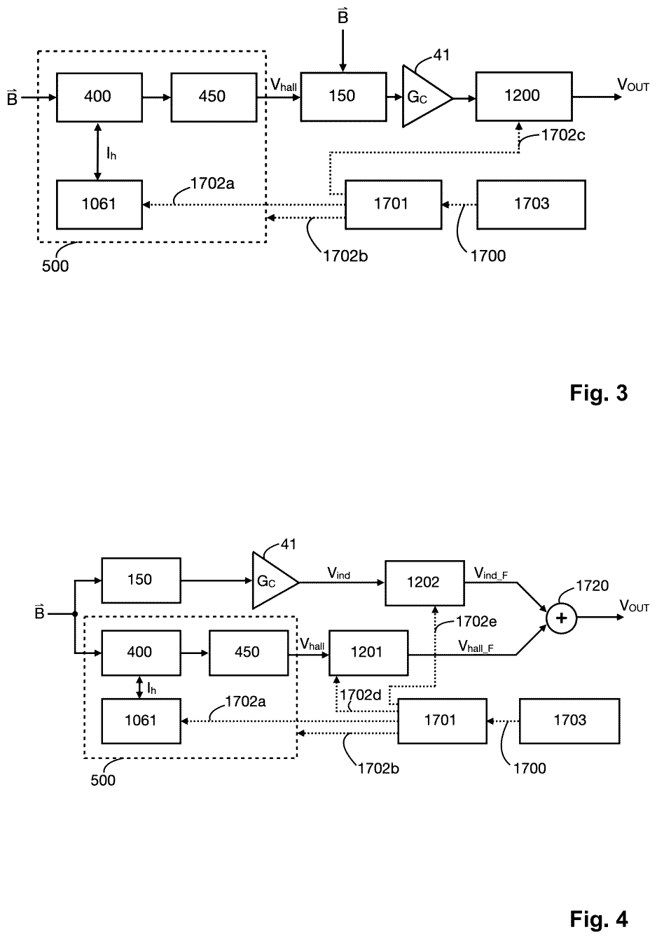

FIG. 3 a block diagram of an embodiment of a magnetic field sensor subsystem which is connected in series with an induction coil as an inductive element;

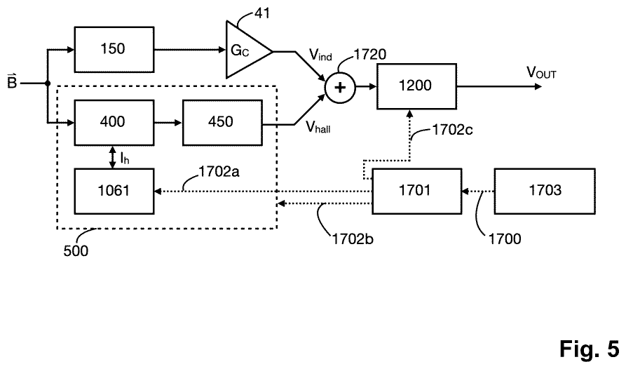

FIG. 4 a block diagram of an embodiment of a magnetic field sensor subsystem which is connected in parallel with an induction coil as an inductive element, whereby the respective signal paths each have a separate first-order low-pass filter;

FIG. 5 a block diagram of a further embodiment of a magnetic field sensor subsystem, which is connected in parallel with an induction coil as an inductive element, whereby the two respective signal paths have a common first-order low-pass filter.

### DETAILED DESCRIPTION OF THE FIGURES

FIG. 1 shows a frequency-voltage diagram in which the respective frequency response of partial voltages of a magnetic field sensor system connected to an induction coil as an inductive element is plotted as a function of the frequency of a magnetic field \vec{B}.

The Vₕₐₗₗ curve shows the frequency response of an unfiltered output voltage of a magnetic field sensor subsystem.

The curve V_{hall_F} shows the frequency response of an output voltage of a magnetic field sensor subsystem filtered with a first-order low-pass filter.

The curve V_{ind} shows the frequency response of an unfiltered output voltage of an inductive element.

The curve V_{ind_F} shows the frequency response of an output voltage of an inductive element filtered with a first-order low-pass filter.

The Vₒᵤₜ curve shows the frequency response of the summed low-pass filtered partial voltage Vₕₐₗₗ and V_{ind}.

The cut-off frequency f_{co} of the first-order low-pass filter is also plotted on the x-axis.

The low-pass filtered partial voltages Vₕₐₗₗ and V_{ind} are matched in such a way that the respective amplitude responses of the output signals of a magnetic field sensor subsystem and the output signal of an inductive element are congruent.

Both amplitude responses of the low-pass filtered partial voltages Vₕₐₗₗ and V_{ind} intersect at the cut-off frequency f_{co} of the first-order low-pass filter.

FIG. 2 shows a block diagram of an embodiment of a magnetic field sensor subsystem 500 comprising three interconnected subsystems 400, 450 and 1061, as well as supply terminals V₊ and V₋ and electrical contact terminals 501, 502 for outputting an unfiltered output signal Vₕₐₗₗ.

The subsystem 400 of an embodiment of a magnetic field sensor subsystem 500 comprises a magnetic field sensor 100, to which the switchable contacts 110, 111, 112 are assigned and which can be switched via the contact terminal 503 with control signals indicated by dashed lines.

In the illustrated embodiment, the magnetic field sensor 100 comprises the magnetic field sensor element 10, which can be selectively coupled via the switchable contacts 110, 111, 112. These switchable contacts thus enable the well-known spinning current technique, whereby the circuit is preferably designed in such a way that the unamplified sensor signal is modulated by the switchable contacts 110 and 111 and the switchable contact 112 serves to contact the sensor with the amplifier during the measuring process.

The magnetic field sensor 100 can comprise one or more such magnetic field sensor elements 10 and these can, for example, be designed as planar or vertical Hall sensor elements. The one or more magnetic field sensor elements 10 are connected by means of their connections 1, 2, 3 and 4.

In the case of several magnetic field sensor elements 10, such magnetic field sensor elements 10 can be connected in parallel or in series with one another or connected together in a combination of series and/or parallel connection.

Moreover, in embodiments of a magnetic field sensor subsystem 500, other types of magnetic field sensors may be used, such as sensors that use a galvano-magnetic or magneto-resistive effect (xMR sensors), for example, a magnetic tunnel resistor (TMR), a giant magneto resistor (GMR), a colossal magneto-resistive effect (CMR), or an anisotropic magneto-resistive effect (AMR).

The subsystem 450 of an embodiment of a magnetic field sensor subsystem 500 preferably comprises an amplifier 40 for amplifying the modulated magnetic field sensor signal Vₕ and switchable contacts 113 connected thereto for signal demodulation in order to provide the output signal Vₕₐₗₗ between the contact terminals 502 and 503. The dashed control signals for the switchable contacts 113 are fed in via contact terminal 503.

The subsystem 1061 of an embodiment of a magnetic field sensor subsystem 500 further comprises a power source 61 for supplying power to the magnetic field sensor 100.

The current Iₕ of the current source 61 of the subsystem 1061 is preferably variable by means of one or more switched capacitor circuits 62 as a function of the current source clock signal 1702a indicated by a dashed line, which is fed in via the contact terminal 504.

FIG. 3 shows an embodiment of a magnetic field sensor system comprising a magnetic field sensor subsystem 500, wherein the magnetic field sensor subsystem 500 is connected in series with an inductive element 150, for example in the form of an induction loop or an induction coil. The magnetic field sensor subsystem 500, based on the spinning current technique with the switches 110, 111, 112, 113 not shown, serves to realise this and comprises the subsystem 1061 for the electrical supply of the subsystem 400.

The output signal Vₕₐₗₗ of the subsystem 450, or the magnetic field sensor subsystem 500, is present as the input signal of the series-connected inductive element 150. The resulting, summed signal of the magnetic field sensor subsystem 500 and the inductive element 150 can preferably be amplified with a downstream amplifier 41 with an amplification factor Gc and the signal can be fed to a first-order low-pass filter 1200.

The sum of the signals from the magnetic field sensor subsystem 500 and the signal from the inductive element 150 is thus filtered.

The clock signals indicated by dashed lines, namely the current source clock signal 1702a for controlling the current source 1061, the spinning current clock signal 1702b for controlling the switches 110, 111, 112, 113 for the spinning current technique, i.e. signal modulation and signal demodulation, and the filter clock signal 1702c for controlling the switched capacitor low-pass filter (low-pass filter with switched capacitors) are formed by coordination with the common clock signal 1700.

It can also be seen from FIG. 3 that the subsystem 1061 and the first-order low-pass filter 1200 can be controlled using a common clock signal as a reference clock signal. This means that the respective clock signals, namely the current source clock signal 1702a and the filter clock signal 1702c, are coordinated with the common clock signal.

The clock signals 1702a, 1702b, 1702c are coordinated and provided by the compensation control unit 1701. The compensation control unit 1701 is designed in such a way that the clock signals 1702a, 1702b, 1702c are derived from the reference clock signal 1700. The reference clock signal 1700 is provided by the oscillator 1703 as a clock generator.

The clock signals 1702a and 1702c are also provided by the compensation control unit 1701 such that the clock signals are proportional to the reference clock signal 1700.

The output signal Vₒᵤₜ of the magnetic field sensor system is ultimately present between the two contact terminals 501 and 502 not shown.

FIG. 4 shows a block diagram of an embodiment of a magnetic field sensor system with a magnetic field sensor subsystem 500 comprising the subsystems 400, 450 and 1061. The magnetic field sensor subsystem 500 is connected in parallel with an inductive element 150, for example in the form of an induction loop or an induction coil.

The output signal of the inductive element 150 can preferably be amplified with a downstream amplifier 41 with an amplification factor Gc before it is fed to the first-order low-pass filter 1202 as the input signal V_{ind} as an amplified output signal V_{ind}, if necessary. The first-order low-pass filter 1202 outputs V_{ind_F} as output signal of the low-pass filtered and, if necessary, amplified output voltage of the induction coil.

The output signal Vₕₐₗₗ of the subsystem 450, or the magnetic field sensor subsystem 500, is present in the parallel branch of the circuit as the input signal of the first-order low-pass filter 1201. The first-order low-pass filter 1201 outputs V_{hall_F} as output signal of the low-pass filtered output voltage of the subsystem 450 or the magnetic field sensor subsystem 500.

The two output signals V_{ind_F} and V_{hall_F} are summed and are ultimately present as the summed output signal Vₒᵤₜ of the sensor system between the two contact terminals 501 and 502 not shown.

The first-order low-pass filters 1201 and 1202 arranged along the signal paths of the embodiment of the illustrated magnetic field sensor system before summation can be controlled by the respective filter clock signals 1702d and 1702e.

The clock signals 1702a, 1702b, 1702d, 1702e are coordinated and provided by the compensation control unit 1701. The compensation control unit 1701 is designed in such a way that the clock signals 1702a, 1702b, 1702d, 1702e are derived from the reference clock signal 1700. The reference clock signal 1700 is provided by the oscillator 1703 as a clock generator.

The clock signals 1702a, 1702d, 1702e are also provided by the compensation control unit 1701 such that the clock signals are proportional to the reference clock signal 1700.

FIG. 5 shows a block diagram of an embodiment of a magnetic field sensor system with a magnetic field sensor subsystem 500 comprising the subsystems 400, 450 and 1061. The magnetic field sensor subsystem 500 is connected in parallel with an inductive element 150, for example in the form of an induction loop or an induction coil.

The output signal of the induction coil 150 can preferably be amplified with a downstream amplifier 41 with an amplification factor Gc, before it is output as an optionally amplified output signal V_{ind} for summation.

The output signal Vₕₐₗₗ of the subsystem 450, or the magnetic field sensor subsystem 500, is output in the parallel branch from the output signal Vₕₐₗₗ for summation.

The both output signals V_{ind} and Vₕₐₗₗ are summed and are finally present as summed signal as an input signal at the first-order low-pass filter 1200. The first-order low-pass filter 1200 outputs Vₒᵤₜ as output signal of the low-pass filtered summed signal from the output voltage of the inductive element 150, which may be amplified, and the output voltage of the magnetic field sensor subsystem 500.

The output signal Vₒᵤₜ of the magnetic field sensor system is ultimately present between the two contact terminals 501 and 502 not shown.

It can also be seen from FIG. 5 that the subsystem 1061 and the first-order low-pass filter 1200 can be controlled by a common clock signal as reference clock signal 1700. This means that the respective clock signals, namely the current source clock signal 1702a and the filter clock signal 1702c, are coordinated with the common clock signal.

The clock signals 1702a, 1702b, 1702c are coordinated and provided by the compensation control unit 1701. The compensation control unit 1701 is designed in such a way that the clock signals 1702a, 1702b, 1702c are derived from the reference clock signal 1700. The reference clock signal 1700 is provided by the oscillator 1703 as a clock generator.

The clock signals 1702a and 1702c are also provided by the compensation control unit 1701 such that the clock signals are proportional to the reference clock signal 1700.

List of reference signs

| No. | Reference sign |
|---|---|
| 1 | Connection contact |
| 2 | Connection contact |
| 3 | Connection contact |
| 4 | Connection contact |
| 40 | Amplifier |
| 41 | Amplifier |
| 61 | Power source |
| 62 | Switched capacitor circuit |
| 100 | Magnetic field sensor |
| 110 | Switchable contacts |
| 111 | Switchable contacts |
| 112 | Switchable contacts |
| 113 | Switchable contacts |
| 150 | Inductive element |
| 400 | Subsystem |
| 450 | Subsystem |
| 500 | Magnetic field sensor subsystem |
| 501 | Contact clamp |
| 502 | Contact clamp |
| 503 | Contact clamp |
| 1061 | Subsystem |
| 1200 | Low-pass filter |
| 1201 | Low-pass filter |
| 1202 | Low-pass filter |
| 1700 | Clock signal |
| 1701 | Compensation control unit |
| 1702a | Current source clock signal |
| 1702b | Spinning current clock signal |
| 1702c | Filter clock signal |
| 1702d | Filter clock signal |
| 1702e | Filter clock signal |
| 1703 | Oscillator |
| 1720 | Summer |
| B [symbol] | Magnetic field as sensor input signal |
| V₊ | Positive supply voltage |
| V₋ | Negative supply voltage |
| Vₕ | Magnetic field sensor signal |
| lₕ | Supply current |
| G_{c} | Amplification factor |
| Gₕ | Amplification factor |
| Vₕₐₗₗ | Unfiltered output voltage of the magnetic field sensor |
| Vₕₐₗₗ_F | Filtered output voltage of the magnetic field sensor |
| V_{ind} | Unfiltered output voltage of the inductive element |
| V_{ind}_F | Filtered output voltage of the inductive element |
| Vₒᵤₜ | Output voltage of the magnetic field sensor system |
| Kₕ | Proportionality coefficient |
| K_{f} | Proportionality coefficient |
| f_{cl} | Frequency of the reference clock |
| f_{co} | Cut-off frequency of the low-pass filter |

[symbol]

indicates data missing or illegible when filed

1. Magnetic field sensor system having a temperature response compensated output signal (Vₒᵤₜ), the magnetic field sensor system comprising a magnetic field sensor subsystem (500) comprising interconnected subsystems (400, 1061) for temperature response compensation of the output signal (Vₒᵤₜ), wherein
a first subsystem (400) comprises one or more magnetic field sensors (100) selected from the group consisting of Hall effect sensors or other galvano-magnetic sensors; and
a second subsystem (1061) of the magnetic field sensor subsystem (500) comprising a power source (61) for supplying power to the one or more magnetic field sensors (100);
wherein the magnetic field sensor system further comprises a low pass filter (1200) and one or more inductive elements (150) electrically connected to the one or more magnetic field sensors (100) of the subsystem (400) directly or via a summer (1720), and for temperature response compensation, the current source (61) supplies the one or more magnetic field sensors (100) with a supply current (In) in such a way that the temperature response of the one or more magnetic field sensors (100) can be compensated by means of the supply current (In) as a function of a current source clock signal (1702a) derived from an oscillator (1703).

2. Magnetic field sensor system according to claim 1, wherein the low-pass filter (1200) is designed to change its cut-off frequency (f_{co}) as a function of a filter clock signal (1702c) in such a way that the temperature dependence of at least one magnetic field sensor (100) can additionally be compensated.

3. Magnetic field sensor system according to claim 1, wherein the frequency of the filter clock signal (1702c) and/or the current source clock signal (1702a) is/are variable in the event of a deviation from a nominal frequency such that the magnetic sensitivity of the one or more magnetic field sensors (100) and the cut-off frequency (f_{co}) of the low-pass filter are proportional to the frequency of a common clock signal (1700).

4. Magnetic field sensor system according to claim 1, wherein the current source (1061) for the magnetic field sensor (100) and/or the low-pass filter (1200) each comprise one or more switched capacitor circuits.

5. Magnetic field sensor system according to claim 4, wherein the capacitance of one or more capacitors of the one or more switched capacitor circuits is programmable.

6. Magnetic field sensor system according to claim 3, wherein the common clock signal (1700) is formed by synchronisation of the filter clock signal (1702c) and the current source clock signal (1702a).

7. Magnetic field sensor system according to claim 2, wherein the magnetic field sensor system further comprises a compensation control unit (1701) configured to provide the filter clock signal (1702c), the current source clock signal (1702a) or any combination thereof.

8. Magnetic field sensor system according to claim 1, wherein the magnetic field sensor subsystem (500) comprises a further subsystem 450 comprising an amplifier (40) for amplifying an output voltage (Vₕ) output from at least one magnetic field sensor (100) as a magnetic field sensor signal modulated by switchable contacts (112).

9. Magnetic field sensor system according to claim 8, wherein the magnetic field sensor system and/or the magnetic field sensor subsystem (500) for a spinning current operation of a magnetic field sensor (100) and/or a chopper stabilisation of the amplifier (40) has, in addition to the switchable contacts (112), switchable contacts (110, 111) which both relate to the same clock signal (1700).

10. Magnetic field sensor system according to claim 1, wherein the oscillator (1703) is a voltage-controlled oscillator.

11. Method for temperature response compensation of an output signal (Vₒᵤₜ) of a magnetic field sensor system comprising a magnetic field sensor subsystem (500) comprising interconnected subsystems (400, 1061), wherein
a first subsystem (400) comprises one or more magnetic field sensors (100) selected from the group consisting of Hall effect sensors or other galvano-magnetic sensors; and
a second subsystem (1061) of the magnetic field sensor subsystem (500) comprising a power source (61) for supplying power to the one or more magnetic field sensors (100);
wherein the magnetic field sensor system further comprises a low-pass filter (1200), and one or more inductive elements (150) electrically connected to this or these magnetic field sensors (100) of the subsystem (400) directly or via a summer (1720),
wherein the method comprises the steps of:
determining a supply current (In) as a function of a current source clock signal (1702a) derived from an oscillator (1703), thereby compensating for the temperature behaviour of the one or more magnetic field sensors (100); and
supplying the one or more magnetic field sensors (100) with the determine supply current (Iₕ) using the current source (61).

12. Method for temperature response compensation of an output signal (Vₒᵤₜ) of a magnetic field sensor system according to claim 1, the method comprising the steps of:
determining a supply current (Iₕ) as a function of a current source clock signal (1702a) derived from an oscillator (1703), thereby compensating for the temperature behaviour of the one or more magnetic field sensors (100); and
supplying the one or more magnetic field sensors (100) with the determined supply current (Iₕ) using the current source (61).
